(19) United States
(12) Patent Application Publication
(10) Pub. No.: US 2003/0006412 A1
(43) Pub. Date: Jan. 9, 2003

(54) Semiconductor device, semiconductor test structure and method for fabricating a semiconductor device

(76) Inventors: Andreas Martin, Munchen (DE); Josef Fazekas, Munchen (DE)

Correspondence Address: LERNER AND GREENBERG, P.A., POST OFFICE BOX 2480, HOLLYWOOD, FL, 33022-2480, US

(21) Appl. No.: 09/899,683

(22) Filed: Jul. 5, 2001

(51) Int. Cl. H01L 21/66; G01R 31/26; H01L 29/76

(52) U.S. Cl. 257/48; 257/296; 257/379; 438/14; 438/15; 438/18

(57) ABSTRACT

An insulation region comprising a dielectric is applied to an electrically active region, and then an electrically conductive region which is connected to an electrically conductive supply conductor is applied to the insulation region. An auxiliary conductor track, which is connected to a region which is highly doped at least with doping atoms of a first conductivity type, is arranged adjacent to the electrically conductive supply conductor.

The invention relates to a semiconductor device, a semiconductor test structure and a method for fabricating a semiconductor device.

A semiconductor test structure of this type is known from [1].

During the fabrication of large-scale integrated circuits which have, for example, a multiplicity of MOS transistors (Metal Oxide Semiconductor Transistors), plasma process steps, that is to say process steps in which plasma is used as part of the processing or fabrication of the device or as part of the interconnecting, are often provided as part of the fabrication process. The plasma used in a plasma process step of this type is able to electrically charge an electrically conductive supply conductor (connection line) to a gate region of a field-effect transistor and to electrically charge the gate region. The electric charge, which accumulates on the supply conductors and in the gate region, flows out of a dielectric across the insulation region located beneath the gate region and may damage or even destroy the latter if the plasma process has not been suitably optimized in an appropriate way during fabrication. For example, in particular leakage current paths may be generated, which in the fully processed transistor may lead to damage and to a reduced service life or to a complete failure.

This damage to the insulation region, i.e. the degradation and/or the unintentional introduction of leakage current paths into the dielectric, is known as plasma-induced damage (PID) caused by charging and, as shown in [2], for example, is dependent on the antenna ratio (AR) of that surface of the supply conductors which is brought into contact with the plasma to the active dielectric area of the field-effect transistor, i.e. to that surface of the dielectric to which the gate region is applied.

The ratio of the surface areas of the supply conductors which are brought into contact with the plasma to the active dielectric surface area is continuously changing during the fabrication process, i.e. the antenna ratio is not constant (cf. [2]).

The maximum service life and the reliability of the chips and of the field-effect transistors located therein may be impaired considerably by different levels of plasma-induced damage during fabrication; the damage may end up being considerably greater than was planned in the layout of the chip.

To enable the reliability of the components used in a chip to be estimated, in particular of the field-effect transistors (or also capacitors), for example with regard to the degradation of hot carriers or mobile ions, it is desirable for the influence of plasma-induced damage as far as possible not to be included in the measurements.

For this reason, the influence of the plasma-induced damage caused by charging by means of the protection structure, i.e. by means of the semiconductor protection structure, should be as far as possible minimized or ruled out altogether. Moreover, to obtain the best possible quantitative information about the degree of plasma-induced damage caused by charging, it is highly important to design corresponding semiconductor PID test structures with an accurately defined ratio of the surface area of the electrically conductive supply conductor to the gate region which is brought into contact with the plasma to the active dielectric surface area.

In the case of the semiconductor test structures described in [1] and [2], there is provision for protection diodes to be provided in process levels which are later and therefore higher than the transistor process levels in terms of the fabrication process, in order to reduce the plasma-induced charges on the supply conductors, i.e. to allow the charges to leak away via these conductors. Alternatively, the use of what are known as line jumpers is described for the purpose of minimizing supply conductors and therefore the charging.

In the context of this description, the term process level is to be understood as meaning, for example, a wiring level in a semiconductor fabrication process, or generally a level in the semiconductor device which is fabricated or processed during at least one process step.

A drawback of the use of a protection diode is, in particular, that only one type of electric charge carriers can leak away. A further drawback is that the protection diode affects the performance of the device, and the protection diode can only be connected after the first metallization level.

Therefore, the invention is based on the problem of reducing the influence of plasma-induced damage caused by charging on the electronic component.

The problem is solved by the semiconductor device, the semiconductor test structure and the method for fabricating a semiconductor device having the features given in the independent patent claims.

A semiconductor device, for example a chip on a wafer, has a substrate. An electrically active region is arranged in or on the substrate. The electrically active region may be an electrode of a capacitor, preferably of an MIS capacitor (Metal Insulator Semiconductor Capacitor), or may also, for example, be a channel region of a field-effect transistor.

An electrically insulating insulation region comprising a dielectric is arranged on the electrically active region. In turn, an electrically conductive region, for example a further electrode or a gate region of a field-effect transistor, is applied to the insulation region.

The electrically conductive region is electrically coupled to an electrically conductive supply conductor, i.e. is connected to the latter.

Furthermore, there is an electrically conductive auxiliary conductor track arranged adjacent to the electrically conductive supply conductor and is electrically coupled to at least one region of the substrate or the well, for example in the substrate, which is highly doped with doping atoms of a first conductivity type.

In this context, it should be pointed out that the invention is not restricted to an MIS capacitor or to a field-effect transistor, but rather is suitable for any stack structure in which an insulation region, preferably comprising a dielectric, can be used on an electrically active region, i.e. for example, including an electrically conductive region, and then a further electrically conductive region, which is coupled to an electrically conductive supply conductor, can be applied to this insulation region; by way of example it can also be used for an MIM capacitor (Metal Insulator Metal Capacitor), a polysilicon-polysilicon capacitor, a memory cell, a thyristor or other power semiconductor components with a corresponding structure.

The term auxiliary conductor track is to be understood as meaning a conductor track which, in terms of the functionality of the semiconductor device, has no function within the context of the circuit components provided in the semiconductor device and which serves only to dissipate accumulations of charge carriers which occur on the electrically conductive supply conductor and the electrically conductive region on the insulation region during a plasma process, in particular during a plasma etching process, into the highly doped region, which is connected to the auxiliary conductor track, via the auxiliary conductor track, in order in this way to reduce and generally even minimize damage to the dielectric which occurs during a plasma etching process.

Clearly, the invention can be regarded as consisting in the fact that, during a plasma etching process, or in general during a plasma process, charge carriers which accumulate on an electrically conductive supply conductor are dissipated via an electrically conductive auxiliary conductor track, for example into one or more highly doped regions, and the electrically conductive supply conductor and the auxiliary conductor track are only electrically decoupled in process engineering terms at the end of the plasma etching step.

A source region of a field-effect element and a drain region of a field-effect element may be provided in the semiconductor device. In this case, the active region is arranged between the source region and the drain region and forms a channel region of the field-effect element. In this case, the electrically conductive region forms the gate region of a field-effect element, for example of a field-effect transistor.

The electrically active region may form a first electrode of a capacitor, and the electrically conductive region may form a second electrode of the capacitor.

According to a refinement of the invention, there is at least one second region which is highly doped with doping atoms of a second conductivity type and is connected to the electrically conductive auxiliary conductor track.

Preferably, the highly doped regions are arranged in the substrate and are used to dissipate charge carriers into the base material, i.e. for example, into the substrate. One of the two highly doped regions or both highly doped regions are preferably accommodated in a well in the substrate. According to a further configuration of the invention, it is provided that two highly doped regions are arranged in the well and one or two further highly doped regions are arranged outside the well in the substrate and are likewise electrically coupled to the auxiliary conductor track.

The electrically conductive region and the electrically conductive supply conductor may be arranged in different processing levels of the semiconductor device, in which case the electrically conductive supply conductor is preferably arranged above the electrically conductive region.

In this context, the term “above” is to be understood as meaning that a layer which is situated above a further layer, during the fabrication process of a semiconductor device, is formed in a process step which follows the step of the fabrication of the further layer.

In this case, the electrically conductive supply conductor and the electrically conductive auxiliary conductor track are arranged in the same processing level of the semiconductor device.

In this context, it should be noted that, during the fabrication of the semiconductor device, prior to a plasma etching step which is applied to the electrically conductive supply conductor and the auxiliary conductor track, these two structures are still electrically coupled to one another, since they are only formed after patterning of a metal layer has taken place.

On account of the plasma etching step, the electrically conductive supply conductor and the electrically conductive auxiliary conductor track are preferably only electrically decoupled from one another towards the end of the plasma etching step, i.e. only towards the end of the actual plasma etching process are the charge carriers which are then still forming and collect on the electrically conductive supply conductor passed to the gate region, i.e. generally to the electrically conductive region, and are in this way able to damage the dielectric, reduce the chip performance or distort measurement results in the context of reliability tests for transistors, for example with regard to the degradation of hot carriers or mobile ions.

However, during most of the duration of the plasma etching process step, the electrically conductive supply conductor and the electrically conductive auxiliary conductor track are electrically coupled to one another, so that the charge carriers which accumulate on the two structures can leak away via the regions which are highly electrically doped with doping atoms.

According to one configuration of the invention, the electrically conductive region is formed from highly doped polysilicon.

The electrically conductive supply conductor and/or the auxiliary conductor track may contain or be formed from metal or a metal alloy. The electrically conductive supply conductor and/or the auxiliary conductor track preferably contain(s) at least one of the following metals or is/are formed from these metals:

aluminium, and/or

copper, and/or

gold, and/or

an alloy of at least one of the abovementioned metals.

The electrically conductive supply conductor and/or the auxiliary conductor track may in general terms contain any suitable electrically conductive material or may be formed from such a material, for example

polysilicon,

silicide.

The substrate may contain or be formed from at least one of the following semiconductor materials:

monoelemental semiconductor material from main group IV of the periodic system, preferably silicon,

compounds of a plurality of monoelemental, different semiconductor materials from main group IV of the periodic system, preferably silicon-germanium (SiGe),

III-V semiconductor material, preferably gallium arsenide, indium phosphide,

II-VI semiconductor material.

Particularly if the electrically conductive region and the electrically conductive supply conductor are arranged at different process levels, i.e. therefore at different levels within the semiconductor device, they are coupled in particular via at least one contact hole which is filled with electrically conductive material.

According to an exemplary embodiment of the invention, this electrically conductive coupling contains at least one of the following metals:

tungsten, and/or

aluminium, and/or

copper, and/or

gold, and/or

an alloy of at least one of the abovementioned metals.

According to one configuration of the invention, the auxiliary conductor track is arranged adjacent to and at a distance from the electrically conductive supply conductor, which distance is selected as a function of a process characteristic of a process step as part of the fabrication and/or processing of the auxiliary conductor track and/or the electrically conductive supply conductor. This allows further optimization of the invention taking into account the corresponding process characteristic.

The distance is preferably selected as a function of a process characteristic of a plasma etching process for the fabrication and/or processing of the auxiliary conductor track and/or of the electrically conductive supply conductor.

If the plasma etching process etches relatively large exposed surfaces which come into contact with the plasma more quickly than relatively small surfaces, it is advantageous for the distance to be selected in accordance with the maximum resolution of the overall process, for example, with current process technology, in the region of 0.1 μm, 0.3 μm, etc.

However, if the plasma etching process is set up in such a manner that small areas are etched more quickly than large areas, it is advantageous for the distance between the auxiliary conductor track and the electrically conductive supply conductor to be selected to be as great as possible, so that it is in each case ensured that the electrical coupling between the electrically conductive supply conductor and the auxiliary conductor track is only electrically interrupted towards the end of the plasma etching process. In this context, the free space available on the chip in the layout should be taken into account when selecting the distance.

The selection of the distance is reflected, within the scope of the fabrication process, in the corresponding arrangement and patterning of the photoresist on a respective metal layer from which the electrically conductive supply conductor and the auxiliary conductor track are formed.

Clearly, therefore, according to the invention the different rate of removal of the metal, which in [2] is portrayed as a drawback of a plasma etching process, is utilized during a plasma etching process to achieve the best possible dissipation of the charge carriers into the respective highly doped region during a plasma etching process and therefore to reduce the damage to the dielectric during a plasma etching process.

According to an alternative configuration of the invention, a further electrically active region is arranged in the substrate or on the substrate, and a further insulation region comprising a dielectric, which may be identical to the dielectric of the insulation region or may also be a different dielectric, is arranged on the further electrically active region. According to this configuration of the invention, a further electrically conductive region, which is electrically coupled to a further electrically conductive supply conductor, is arranged on the further insulation region. That surface of the further insulation region on which the further electrically conductive region is arranged is the same size as or larger than that surface of the insulation region on which the electrically conductive region is arranged. Depending on the space available, the ratio of the surface area of the further insulation region may be a factor of up to 1000. Alternatively or in addition, the thickness of the further insulation region, i.e. the thickness of the further dielectric, may be selected to be less than the thickness of the insulation region, i.e. the thickness of the dielectric which is to be protected.

Clearly, according to this configuration of the invention, a semiconductor element of the same structure but with an increased ratio of the surface area of the further insulation region to the surface area of the insulation region and/or with a thinner dielectric is provided, by means of which, during the plasma etching process generated carriers, at the start of this process the electrically conductive supply conductor, the auxiliary conductor track and the electrically conductive further supply conductor are coupled to one another are dissipated to an increased extent towards the further insulation region. In the further dielectric, the damage caused to the dielectric by the charge carriers in the insulation region is reduced considerably on account of the enlarged active dielectric surface area and/or on account of the thinner dielectric.

The invention is particularly suitable for testing a semiconductor arrangement, or in other words the semiconductor device is particularly advantageously a semiconductor test structure for testing a semiconductor arrangement.

However, it should be noted that the invention is suitable for any desired electric circuit and can be used accordingly.

In a method for fabricating a semiconductor device, an electrically active region is arranged in a substrate or on a substrate. An insulation region comprising a dielectric is applied to the electrically active region, and then an electrically conductive region is in turn applied to the insulation region. An electrically conductive supply conductor, which is connected to the electrically conductive region, is formed. Furthermore, an electrically conductive auxiliary conductor track, which is arranged adjacent to the electrically conductive supply conductor, is formed, as is at least one region which is highly doped with doping atoms of a first conductivity type and is connected to the electrically conductive auxiliary conductor track.

According to the invention, any desired number of electrically conductive layers and therefore supply conductors can be arranged above one another and electrically coupled to the respective electrically conductive region, for example the gate region.

Accordingly, any desired number of electrically conductive supply conductors in some cases also in a partial circuit region with many electrically conductive regions used with the respective highly doped region may be coupled to one another, although in each case at least one auxiliary conductor track, which has no function after the plasma etching process has been completed, is provided, and during the plasma etching process, in particular at the beginning of the plasma etching process, is still coupled to the respective electrically conductive supply conductors leading to the electrically conductive regions.

It is also possible for electrically conductive regions to remain electrically connected to one another in such a manner during the plasma process, as a result of further, additional auxiliary conductor tracks, which are preferably smaller than the auxiliary conductor track, being incorporated between existing electrically conductive supply conductors.

Therefore, the invention is eminently suitable for structures or circuits not only in the field of testing, i.e. in a test chip, but also even in a product chip.

According to the invention, the auxiliary conductor track which has no function may be regarded, drawing an analogy to structural engineering, as lost formwork, i.e. according to the invention an element is formed or provided which only has a function during the fabrication process, but no longer has any function after the semiconductor device has been completed.

Exemplary embodiments of the invention are illustrated in the figures and are explained in more detail below.

In the figures, identical elements are provided with identical reference numerals, and:

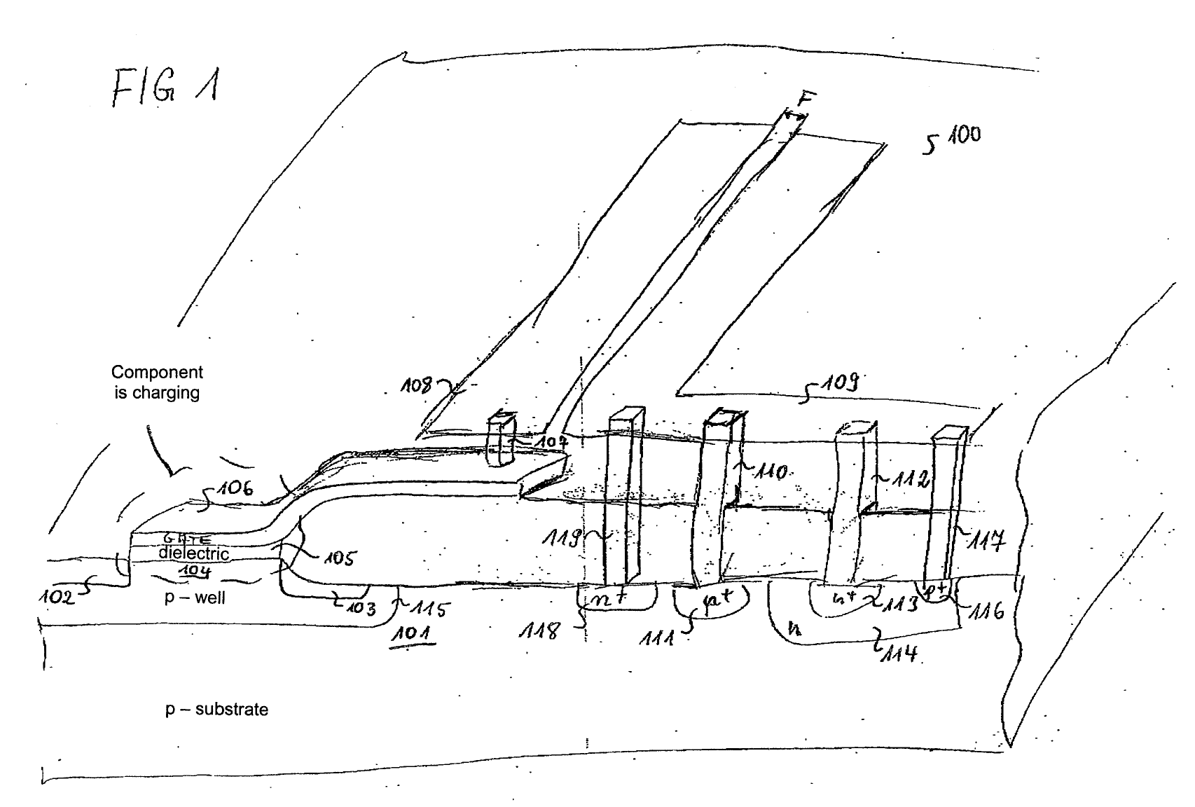

FIG. 1 shows a sketch of a semiconductor device according to a first exemplary embodiment of the invention;

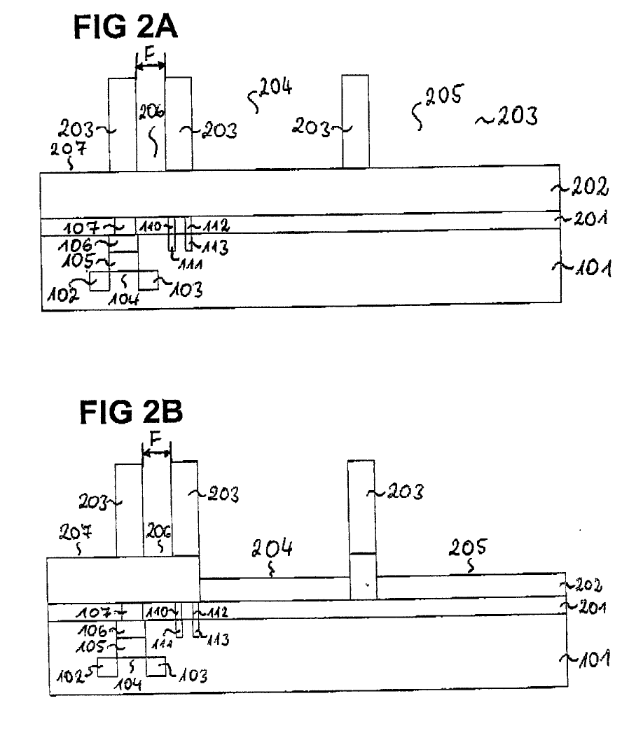

FIGS. 2a to 2d show sketches of the semiconductor device according to the first exemplary embodiment of the invention at different times during the plasma etching process which is used to pattern a metal layer and to form the electrically conductive supply conductor to an electrically conductive region;

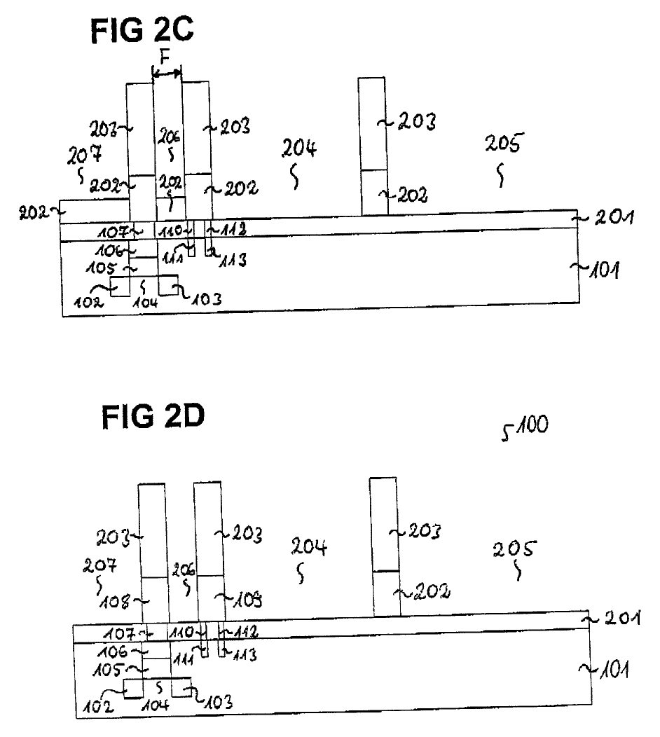

FIG. 3 shows a sketch of a semiconductor device in accordance with a second exemplary embodiment of the invention; and

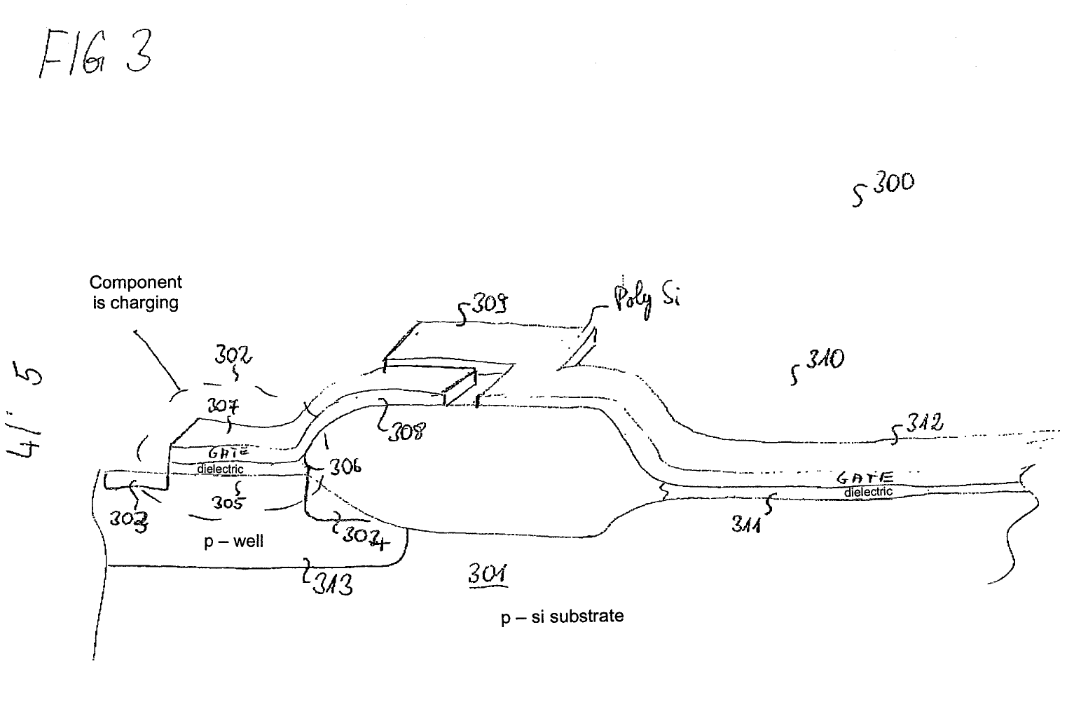

FIG. 4 shows a sketch illustrating an excerpt of a semiconductor device in accordance with a third exemplary embodiment of the invention.

FIG. 1 shows a semiconductor device 100 in accordance with a first exemplary embodiment of the invention.

The semiconductor device 100 has a silicon substrate 101, which is p-doped with boron atoms (10¹⁵ cm⁻³-10¹⁷ cm⁻³), a well 115 which is p-doped with boron atoms (10¹⁶ cm⁻³-10¹⁸ cm⁻³), a source region 102 which is n⁺-doped with arsenic or phosphorus atoms (10¹⁹ cm⁻³-10²¹ cm⁻³) and a drain region 103 which is n⁺-doped with arsenic or phosphorus atoms (10¹⁹ cm⁻³-10²¹ cm⁻³). The source region 102 and the drain region 103 are formed in the p-doped well 115.

A channel region 104, to which a dielectric is applied as insulation material in the insulation region 105, is formed between the source region 102 and the drain region 103.

According to this exemplary embodiment of the invention, silicon dioxide is selected as the dielectric.

Alternatively, the following materials are preferably used as dielectric:

oxynitride (NO),

an ONO structure (oxide-nitride-oxide structure),

silicon nitride (Si₃N₄),

high-k dielectrics,

a stack structure comprising different high-k dielectrics arranged above one another.

A gate region 106 is arranged on the insulation region 105, part of the gate region extending over the dielectric 105. The gate region is formed from polysilicon, doped with 10²⁰ cm⁻³-10²¹ cm⁻³ phosphorus doping atoms.

The gate region 106 is electrically coupled, via a contact hole 107 filled with tungsten, to an electrically conductive supply conductor 108 which is formed from aluminium and is arranged in a processing plane arranged above the gate region 106.

Adjacent to the electrically conductive supply conductor 108, in the same processing level as the electrically conductive supply conductor, there is an auxiliary conductor track 109, which has no function in terms of the actual circuitry of the circuit and in this exemplary embodiment likewise consists of aluminium.

The auxiliary conductor track 109 is coupled, via a first auxiliary contact hole 110 comprising tungsten, to an electrically highly doped region 111 which is arranged in the substrate 101 and is p⁺-doped with boron atoms (10¹⁹ cm⁻³-10²¹ cm⁻³). Therefore, electric chargers (negative or positive), i.e. electrons which accumulate on the electrically conductive supply conductor, the gate region and the auxiliary conductor track during the plasma etching process, can be dissipated into the highly doped region 111 via the first auxiliary contact hole 110.

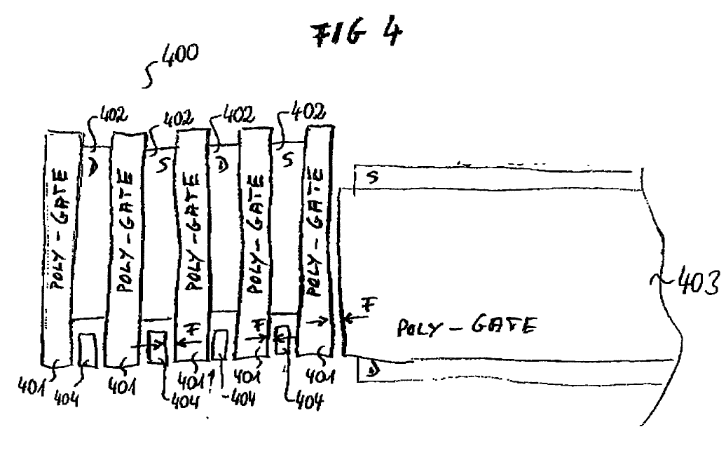

The optional or alternative contact configurations with the second highly doped region 112 and the second auxiliary contact hole 113, and/or with the third highly doped region 116 and the third auxiliary contact hole 117, and/or with the fourth highly doped region 118 and the fourth auxiliary contact hole 119, as shown in FIG. 17 which may also have a predetermined circuitry function within the electric circuit which is actually to be formed, can be used given better availability. The protective action of these alternative contact configurations is influenced by the fact that, depending on the charge polarity, there is in each case a pn diode in the forward direction or in the blocking direction in the discharge current path.

According to the invention, providing a highly doped region of the same conductivity type as the substrate makes it possible for both negative and positive charges which may be brought about by the plasma etching process to be dissipated into the substrate 101 and therefore into the support material, so that it is possible to prevent damage to the dielectric during the plasma etching process for as long as the electrically conductive supply conductor 108 is electrically coupled to the auxiliary conductor track 109.

Furthermore, FIG. 1 shows an optional third electrically highly doped region 116, which is arranged in the n-well 114, is p⁺-doped with boron atoms (10¹⁹ cm⁻³-10²¹ cm⁻³) and is electrically coupled to the auxiliary conductor track 109 via a third auxiliary contact hole 117 comprising tungsten. Furthermore, in FIG. 1 there is an optional fourth electrically highly doped region 118, which is arranged outside the n-well 114 in the substrate 101, is n⁺-doped with arsenic or phosphorus atoms (10¹⁹ cm⁻³-10²¹ cm⁻³) and is electrically coupled to the auxiliary conductor track 109 via a fourth auxiliary contact hole 119 comprising tungsten.

FIG. 2a to FIG. 2d illustrate how, according to the invention, the load on the dielectric is reduced during a plasma etching process. For reasons of clarity, in FIG. 2a to FIG. 2d the wells 114, 115 and the third highly doped region 116, the third auxiliary contact hole 117, the fourth highly doped region 118 and the fourth auxiliary contact hole 119 are not illustrated, and are in any case optional.

First of all, conventional process steps are used to produce the structure illustrated in FIG. 2a.

An electrically insulating layer 201 in which the contact hole 107, which is filled with tungsten, is formed is arranged above the gate region 106.

A metal layer 202 of aluminium is applied to the electrically insulating layer 201, for example by sputtering or deposition or vapour deposition, from which metal layer 202 the electrically conductive supply conductor and the auxiliary conductor track are formed by plasma etching, as explained in more detail below.

A photoresist layer 203, which is patterned by means of a photographic technique, is applied to the metal layer 202, this photoresist layer being patterned in such a manner that those regions of the metal layer 202 which are to be removed by means of a plasma etching process subsequently employed are exposed.

FIG. 2b shows the structure illustrated in FIG. 2a a short time after the plasma etching process has begun.

According to this exemplary embodiment, it is assumed that, on account of the process characteristic of the plasma etching process, relatively large exposed areas 204, 205 which are exposed to the process gas are etched away more quickly than smaller areas 206, 207.

As can be seen from FIG. 2a, the patterned photoresist layer is patterned in such a manner that the regions which cover the electrically conductive supply conductor 108 which is to be formed and the auxiliary conductor track 109 are arranged adjacent to one another at a distance F which corresponds to the maximum process resolution (minimum feature size) of the process used for fabrication of the semiconductor device, which according to this exemplary embodiment is 0.25 μm.

FIG. 2b shows the semiconductor device during the plasma etching process.

FIG. 2b shows that, as described in [2], relatively large exposed regions 204, 205 of metal can be etched away more quickly by the process gas than relatively small surface regions 206, 207.

In FIG. 2b, this means that, after a certain process time during which the exposed regions 204, 205, 206, 207 have been in contact with the plasma, the first exposed regions 204, 205, with a relatively large surface area, have been etched back further than the exposed regions 206, 207 which have a smaller surface area of the metal layer 202.

Finally, FIG. 2c shows the semiconductor device 100 at a time at which the metal layer has been completely etched away in the relatively large, second exposed regions 204, 205.

As can be seen from FIG. 2c, at this time there is still a metallic, i.e. electrically conductive coupling between the electrically conductive supply conductor 108 which is to be formed and the auxiliary conductor track 109, so that the charge carriers which accumulate on the gate region 106, the electrically conductive supply conductor 108 and the auxiliary conductor track 109 can be dissipated, via the first auxiliary contact hole 110 and the second auxiliary contact hole 112 lead into the highly doped regions 111 and 113, into the substrate 101.

FIG. 2d shows the fully processed semiconductor device 100 after the plasma etching step has ended and moreover that part of the metal layer 202 which was free of photoresist has been removed.

Therefore, in this state, only the electrically conductive supply conductor 108 and the auxiliary conductor track 109 are still present, and are now electrically decoupled from one another.

FIG. 3 shows a semiconductor device 300 in accordance with a second exemplary embodiment of the invention.

A first field-effect transistor 302, namely a well 313 which is p-doped with boron atoms (10¹⁶ cm⁻³-10¹⁸ cm⁻³) having a source region 303 which is n⁺-doped with arsenic or phosphorus atoms (10¹⁹ cm⁻³-10²¹ cm⁻³) and a drain region 304, which is likewise n⁺-doped with arsenic or phosphorus atoms (10¹⁹ cm⁻³-10²¹ cm⁻³), has been formed in a silicon substrate 301 which is p-doped with boron atoms (10¹⁵ cm⁻³-10¹⁷ cm⁻³). A channel region 305 is arranged between the source region 303 and the drain region 304. The source region 303 and the drain region 304 are formed in the p-doped well 313.

The gate dielectric comprising silicon dioxide 306 is applied above the channel region 305, and the gate region 307 comprising polysilicon which is highly doped with phosphorus atoms (10²⁰ cm⁻³-10²¹ cm⁻³) and to which an electrically conductive supply conductor 308 made from polysilicon is fitted, is applied to the gate dielectric.

The auxiliary conductor track 309 is situated in the same process level as the electrically conductive supply conductor 308 and is once again arranged next to the electrically conductive supply conductor 308 at a minimum distance, in other words at a distance which corresponds to the minimum feature size.

According to the second exemplary embodiment of the invention, the auxiliary conductor track 309 and the electrically conductive supply conductor 308 are likewise made from highly doped polysilicon.

Furthermore, according to the semiconductor device 300 in accordance with the second exemplary embodiment, there is an auxiliary dielectric structure 310, which has a further insulation region 311, made from a dielectric, according to this exemplary embodiment from silicon dioxide, and to which a further gate region 312, generally a further electrically conductive region 312, is applied.

The auxiliary dielectric structure 310 may be a structure which has no function in the context of the actual electric circuit and is only used to receive the charge carriers, and may be accordingly enlarged with regard to the active dielectric surface area or may be a transistor provided with a dielectric which is thinner or of the same thickness.

According to this exemplary embodiment, that surface of the further insulation region 311 to which the further gate region 311 is applied is larger by a factor of up to 1000 than that surface of the insulation region 306 to which the gate region 307 of the first field-effect transistor 302 is applied.

During the plasma etching process which, according to the second exemplary embodiment, takes place in a similar manner to that illustrated in FIG. 2a to FIG. 2d, and for this reason is not explained in more detail, at the start of the plasma etching process there is an electrically conductive coupling between the gate region 307 of the field-effect transistor, the auxiliary conductor track 309 and the gate region 311 of the auxiliary dielectric structure 310. At this time, charge carriers which accumulate from the plasma on the electrically conductive supply conductor are dissipated primarily by means of the auxiliary dielectric structure 310.

As in the first exemplary embodiment, according to the second exemplary embodiment the electric coupling is only broken towards the end of the plasma etching step, and only then is it no longer possible for charge carriers to be dissipated into the auxiliary dielectric structure 310 via the auxiliary conductor track 309.

FIG. 4 shows a plan view of part of a semiconductor device 400 according to a third exemplary embodiment of the device.

The semiconductor device 400 has a multiplicity of transistors which are arranged next to one another and each have a gate region and an associated gate supply conductor 401 consisting of highly doped polysilicon or a metal or a metal alloy. The source/drain regions 402 of the transistors are in each case arranged between two gate regions or the associated gate supply conductor 401.

At a minimum distance (minimum feature size) F from a gate supply conductor 401 there is an auxiliary conductor track 403 which, in a similar way to the semiconductor device 100 in accordance with the first exemplary embodiment, is coupled to highly doped regions via which electric charge carriers can leak away. Alternatively, as in the semiconductor device 300 in accordance with the second exemplary embodiment, the auxiliary conductor track 403 may be arranged via a further dielectric.

Furthermore, additional auxiliary conductor tracks 404 are arranged in each case between two gate regions or the associated gate supply conductors 401. At the start of the plasma process step, the additional auxiliary supply conductors 404 are electrically coupled to both immediately adjacent gate supply conductors 401, so that a common electrically conductive layer is formed from the gate supply conductors 401, the additional auxiliary conductor tracks 404 and the auxiliary conductor track 403.

The patterning of the common electrically conductive layer before the beginning of the plasma process step takes place in such a manner that the additional auxiliary conductor tracks 404, after the plasma process step has ended, are each arranged at a minimum distance F from in each case one gate supply conductor 401 or the auxiliary conductor track 403.

This exemplary embodiment clearly means that there is no need to provide a continuous auxiliary conductor track in the semiconductor device, but rather conductor tracks which are in some cases already present in the electric circuit can be used as additional auxiliary conductor tracks 404 for dissipating the electric charge to the auxiliary conductor track 403 and, via the latter, into the highly doped regions or into the further dielectrics.

In the text which follows, a few alternatives to the exemplary embodiments outlined above will be described.

It should be noted that the structure of the auxiliary conductor track is not necessarily designed in such a manner that the auxiliary conductor track 109, 309 runs parallel to the electrically conductive supply conductor. The form of the auxiliary conductor track 109, 309 may also be in principle arbitrary, although preferably at least part of the auxiliary conductor track 109, 309 is arranged at a minimum distance from the electrically conductive supply conductor.

According to the invention, it is also possible to reduce the plasma-induced damage caused by electrical charging for the connecting lines, that is to say the supply conductors of the gate regions and the components connected thereto.

In this context, it should be noted that, according to the invention, a plurality of, in principle any desired number of, electrically conductive supply conductors which are in each case arranged at least partially above a dielectric can be electrically coupled to only one auxiliary conductor track, via which auxiliary conductor track all the electrical charge carriers which are then produced can be dissipated into the highly doped regions in the plurality of gate regions or into an auxiliary dielectric structure.

If a semiconductor device in accordance with one of the exemplary embodiments described above is used in a test structure, this device can ensure very accurate determination of the degradation caused by the plasma-induced damage to the transistors with antennae, and it is also possible to avoid damage to the dielectrics of the transistors, which transistors are used to measure transistor parameters.

Furthermore, the mapping accuracy of the semiconductor structure per se can be improved when using a distance of F (Minimum Feature Size) between auxiliary conductor tracks arranged on both sides of a supply conductor.

Furthermore, it should be noted that, when using an auxiliary conductor track according to the invention, direct contact between the surfaces which are at risk of charging is possible, without a decoupling diode, and in this case the polarity of the damaging charge carriers during the plasma-induced damage caused by charging is irrelevant, i.e. it is possible for both electrons and the charge from positive ions to be dissipated, unlike when using protection diodes in accordance with the prior art.

Furthermore, according to the invention, it is possible for further filling structures, without any function, to be provided in the respective metallization levels or in a polysilicon level, i.e. to provide any desired conductor track structures which have no function and, on account of the auxiliary conductor track 109, 309, do not act as surfaces which are charged by the plasma.

Furthermore, according to the invention, it is possible to provide a conductor track bridge, as described in [2]. An additional conductor track bridge of this type allows the charging caused by the plasma to be reduced even further.

To summarize, the invention can clearly be regarded as consisting in the fact that, in a test structure or even in the product layout, or in more general terms in a semiconductor device, auxiliary conductor tracks which run parallel, generally adjacent to one another, leading to at least one gate region or its electrically conductive supply conductor to the upper electrode are provided with a minimum distance between them on all supply conductor levels.

All metallization levels from which conductor tracks are formed are connected to the substrate. Conductor track levels which do not allow substrate connection are connected to electrodes of identical semiconductor components arranged above the gate, which include dielectrics which are thinner or of the same thickness and whose active dielectric surface area is a multiple of that of the semiconductor component which is to be protected.

Furthermore, it is possible to provide a trench between the structure which is to be protected and the highly doped regions in the substrate, by means of which the highly doped regions are electrically more successfully insulated from the structure to be protected, for example from a field-effect transistor or a capacitor. The depth of the trench preferably at least corresponds to the depth of the highly doped regions in the substrate or the depth of the structure in the substrate which is to be protected, but the trench may also penetrate more deeply into the substrate as desired. The trench may be filled with any desired electrically insulating material, for example silicon dioxide as dielectric material.

The following publications are cited in this document:

[1] U.S. Pat. No. 6,028,324

[2] P. Simon, J.-M. Luschies, W. Maly, Antenna Ratio Definition for VLSI Circuits, Proceedings of International Symposium on Plasma Process-Induced Damage, S. 16-20, 1999

1. Semiconductor device
having a substrate,
having an electrically active region arranged in the substrate or on the substrate,
having an insulation region comprising a dielectric arranged on the electrically active region,
having an electrically conductive region arranged on the insulation region,
having an electrically conductive supply conductor which is connected to the electrically conductive region,
having an electrically conductive auxiliary conductor track which is arranged adjacent to the electrically conductive supply conductor, and
having at least one region which is highly doped with doping atoms of a first conductivity type and which is connected to the electrically conductive auxiliary conductor track.

2. Semiconductor device according to claim 1,
having a source region of a field-effect element,
having a drain region of a field-effect element,
the active region being arranged between the source region and the drain region and forming a channel region of a field-effect element, and
the electrically conductive region forming a gate region of a field-effect element.

3. Semiconductor device according to claim 1,
in which the electrically active region forms a first electrode of a capacitor, and
in which the electrically conductive region forms a second electrode of the capacitor.

4. Semiconductor device according to one of claims 1 to 3, having at least one second region which is highly doped with doping atoms of a second conductivity type and which is connected to the electrically conductive auxiliary conductor track.

5. Semiconductor device according to one of claims 1 to 4,
in which the electrically cond uctive region and the electrically conductive supply conductor are arranged in different processing levels of the semiconductor device,
in which the electrically conductive supply conductor and the electrically conductive auxiliary conductor track are arranged in the same processing level of the semiconductor device.

6. Semiconductor device according to one of claims 1 to 4,
in which the electrically conductive region and the electrically conductive supply conductor are arranged in different processing levels of the semiconductor device, and
in which the electrically conductive region contains highly doped polysilicon.

7. Semiconductor device according to one of claims 1 to 6 in which the electrically conductive supply conductor and/or the auxiliary conductor track contains one of the following materials:
polysilicon,
silicide.

8. Semiconductor device according to one of claims 1 to 6, in which the electrically conductive supply conductor and/or the auxiliary conductor track contains metal or a metal alloy.

9. Semiconductor device according to claim 8, in which the electrically conductive supply conductor and/or the auxiliary conductor track contains at least one of the following metals:
aluminium, and/or
copper, and/or
gold, and/or
an alloy of at least one of the abovementioned metals.

10. Semiconductor device according to one of claims 1 to 9, in which the substrate contains at least one of the following semiconductor materials:
direct semiconductor material from main group IV of the periodic system,
a compound of a plurality of monoelemental, different semiconductor materials from main group IV of the periodic system,
III-V semiconductor material,
II-VI semiconductor material.

11. Semiconductor device according to claim 10, in which the substrate contains silicon-germanium as the compound of a plurality of monoelemental, different semiconductor materials from main group IV of the periodic system.

12. Semiconductor device according to claim 10, in which the substrate contains silicon as the direct semiconductor material.

13. Semiconductor device according to one of claims 1 to 12, in which an electrically conductive coupling between the electrically conductive region and the electrically conductive supply conductor and/or an electrically conductive coupling between the auxiliary conductor track and the region which is highly doped with doping atoms of a first conductivity type contains metal.

14. Semiconductor device according to claim 13, in which an electrically conductive coupling between the electrically conductive region and the electrically conductive supply conductor and/or an electrically conductive coupling between the auxiliary conductor track and the region which is highly doped with doping atoms of a first conductivity type contains at least one of the following metals:
tungsten, and/or
aluminium, and/or
copper, and/or
gold, and/or
an alloy of at least one of the abovementioned metals.

15. Semiconductor device according to one of claims 1 to 14, in which the auxiliary conductor track is arranged adjacent to and at a distance from the electrically conductive supply conductor, which distance is selected as a function of a process characteristic of a process step during the production and/or processing of the auxiliary conductor track and/or of the electrically conductive supply conductor.

15. Semiconductor device according to claim 14, in which the auxiliary conductor track is arranged adjacent to and at a distance from the electrically conductive supply conductor, which distance is selected as a function of a process characteristic of a plasma etching process for producing and/or processing the auxiliary conductor track and/or the electrically conductive supply conductor.

16. Semiconductor device according to one of claims 1 to 15,
having a further electrically active region arranged in the substrate, or on the substrate,
having a further insulation region comprising a dielectric arranged on the further electrically active region,
having a further electrically conductive region arranged on the further insulation region,
having a further electrically conductive supply conductor, which is connected to the further electrically conductive region.

17. Semiconductor device according to claim 16, in which that surface of the further insulation region on which the further electrically conductive region is arranged is the same size as or larger than that surface of the insulation region on which the electrically conductive region is arranged.

18. Semiconductor device according to claim 16 or 17, in which the further insulation region has a thickness which is less than or equal to that of the insulation region.

19. Semiconductor test structure for testing a semiconductor arrangement having at least one semiconductor device according to one of claims 1 to 18.

20. Semiconductor protection structure for an integrated circuit having at least one semiconductor device according to one of claims 1 to 18.

21. Method for fabricating a semiconductor device,
in which an electrically active region is arranged in a substrate or on a substrate,
in which an insulation region comprising a dielectric is applied to the electrically active region,
in which an electrically conductive region is applied to the insulation region,
in which an electrically conductive supply conductor, which is connected to the electrically conductive region, is formed,
in which an electrically conductive auxiliary conductor track, which is arranged adjacent to the electrically conductive supply conductor, is formed, and
in which at least one region which is highly doped with doping atoms of a first conductivity type and is connected to the electrically conductive auxiliary conductor track is formed.
